(19) United States
(12) Patent Application Publication
(10) Pub. No.: US 2025/0386430 A1
(43) Pub. Date: Dec. 18, 2025

(54) WIRING CIRCUIT BOARD

(71) Applicant: NITTO DENKO CORPORATION, Osaka (JP)

(72) Inventors: Shoei TETSUKAWA, Osaka (JP); Yusaku TAMAKI, Osaka (JP); Shusaku SHIBATA, Osaka (JP)

(73) Assignee: NITTO DENKO CORPORATION, Osaka (JP)

(21) Appl. No.: 19/235,275

(22) Filed: Jun. 11, 2025

(30) Foreign Application Priority Data
Jun. 14, 2024 (JP) 2024-096722

(51) Int. Cl. H05K 1/02

(52) U.S. Cl. CPC H05K 1/0298

(57) ABSTRACT

A wiring circuit board includes a first insulating layer, a first circuit pattern, a metal support layer, and a second circuit pattern independent of the first circuit pattern. The metal support layer is disposed on the opposite side to the first circuit pattern with respect to the first insulating layer in the thickness direction. The metal support layer is insulated from the first circuit pattern by the first insulating layer, and supports the first circuit pattern and the first insulating layer. The second circuit pattern includes a first terminal. The first terminal has a metal layer continuous with the metal support layer.

### CROSS-REFERENCE TO RELATED APPLICATION

The present application claims priority from Japanese Patent Application No. 2024-96722 filed on Jun. 14, 2024, the content of which is hereby incorporated by reference into this application.

### TECHNICAL FIELD

The present invention relates to a wiring circuit board.

### BACKGROUND ART

Conventionally, there has been known a wiring circuit board including a metal support layer, a base insulating layer disposed on one side of the metal support layer, and a conductor layer disposed on one side of the base insulating layer (for example, see Patent Document 1 below).

### CITATION LIST

### Patent Document

Patent Document 1: Japanese Unexamined Patent Publication No. 2020-188189

### SUMMARY OF THE INVENTION

### Problem to be Solved by the Invention

For the wiring circuit board as described in Patent Document 1, further improvement in the degree of freedom in circuit design is considered.

The present invention provides a wiring circuit board capable of improving the degree of freedom in circuit design.

### Means for Solving the Problem

The present invention [1] includes a wiring circuit board including: an insulating layer; a first circuit pattern disposed on one side of the insulating layer in a thickness direction of the insulating layer; a metal support layer disposed on an opposite side to the first circuit pattern with respect to the insulating layer in the thickness direction, insulated from the first circuit pattern by the insulating layer, and supporting the first circuit pattern and the insulating layer; and a second circuit pattern independent of the first circuit pattern, wherein the second circuit pattern includes a first terminal having a metal layer continuous with the metal support layer.

According to such a configuration, the first terminal of the second circuit pattern has a metal layer that is continuous with the metal support layer.

Therefore, the second circuit pattern independent of the first circuit pattern can be designed by using the metal support layer that supports the first circuit pattern.

As a result, the degree of freedom in circuit design can be improved.

In addition, the metal layer of the first terminal is continuous with the metal support layer, and thus a decrease in the stiffness of the metal support layer caused by forming the second circuit pattern is suppressed as compared with a case where the second circuit pattern is formed by separating a portion of the metal support layer from the metal support layer.

The present invention [2] includes the wiring circuit board described in the above-described [1], wherein the first terminal further includes a terminal covering layer made of metal and covering the metal layer.

According to such a configuration, the metal layer can be protected by the terminal covering layer.

The present invention [3] includes the wiring circuit board described in the above-described [2], further including: a covering layer made of metal and covering the metal support layer, wherein the terminal covering layer is continuous with the covering layer.

According to such a configuration, the metal support layer can be protected by the covering layer.

Further, the terminal covering layer can be formed at the same time as the formation of the covering layer, and thus an increase in the number of steps can be suppressed.

The present invention [4] includes the wiring circuit board described in any one of the above-described [1] to [3], further including: a conductor layer disposed between the insulating layer and the metal support layer in the thickness direction and having a conductivity higher than a conductivity of the metal support layer.

The present invention [5] includes the wiring circuit board described in the above-described [4], wherein the first terminal further includes a terminal conductor layer continuous with the conductor layer.

According to such a configuration, the conductor layer having a high conductivity is provided between the insulating layer and the metal support layer, and the second circuit pattern independent of the first circuit pattern is designed by using the conductor layer.

As a result, it is possible to improve the conductivity performance of the second circuit pattern while improving the degree of freedom in circuit design.

The present invention [6] includes the wiring circuit board described in the above-described [5], wherein the first terminal further includes a terminal covering layer made of metal and covering the terminal conductor layer.

According to such a configuration, the terminal conductor layer can be protected by the terminal covering layer.

The present invention [7] includes the wiring circuit board described in the above-described [6], further including: a covering layer made of metal and covering the metal support layer, wherein the terminal covering layer is continuous with the covering layer.

According to such a configuration, the metal support layer can be protected by the covering layer.

Further, the terminal covering layer can be formed at the same time as the formation of the covering layer, and thus an increase in the number of steps can be suppressed.

The present invention [8] includes the wiring circuit board described in any one of the above-described [5] to [7], wherein the second circuit pattern further includes a second terminal disposed on one side of the insulating layer in the thickness direction and electrically connected to the conductor layer.

According to such a configuration, the first terminal and the second terminal can electrically be connected through the conductor layer.

This enables the transmission of an electric signal or supply of electric power between the first terminal and the second terminal through the conductor layer.

The present invention [9] includes the wiring circuit board described in any one of the above-described [1] to [4], wherein the second circuit pattern further includes a second terminal disposed on one side of the insulating layer in the thickness direction and electrically connected to the metal support layer.

According to such a configuration, the first terminal and the second terminal can electrically be connected through the metal support layer.

This enables the transmission of an electric signal or supply of electric power between the first terminal and the second terminal through the metal support layer.

The present invention includes the wiring circuit board described in any one of the above-described [1] to [9], wherein a one-side surface of the first terminal in the thickness direction is exposed from the insulating layer.

According to such a configuration, the one-side surface of the first terminal in the thickness direction can be used as a coupling surface with an electronic component.

### Effects of the Invention

According to the wiring circuit board of the present invention, it is possible to improve the degree of freedom in circuit design.

### BRIEF DESCRIPTION OF THE DRAWINGS

FIG. 1 is a plan view showing one embodiment of a wiring circuit board of the present invention. In FIG. 1, a second insulating layer, a covering layer, and a terminal covering layer are omitted.

FIG. 2A is a cross-sectional view of the wiring circuit board shown in FIG. 1, taken along line A-A. FIG. 2B is a cross-sectional view of the wiring circuit board shown in FIG. 1, taken along line B-B.

FIGS. 3A to 3C are process diagrams showing the steps of producing the wiring circuit board shown in FIG. 1, FIG. 3A shows a conductor layer forming step, FIG. 3B shows a first insulating layer forming step, and FIG. 3C shows a conductive pattern forming step.

FIGS. 4A to 4C are process diagrams showing the steps of producing the wiring circuit board, following FIG. 3C, FIG. 4A shows a second insulating layer forming step, FIG. 4B shows an outer shape trimming step, and FIG. 4C shows a covering layer forming step.

FIG. 5 is a cross-sectional view of a modified example (1) of the wiring circuit board.

FIG. 6 is a cross-sectional view of a modified example (2) of the wiring circuit board.

FIG. 7 is a cross-sectional view of a modified example (3) of the wiring circuit board.

FIG. 8 is a cross-sectional view of a modified example (4) of the wiring circuit board.

FIG. 9 is a cross-sectional view of a modified example (5) of the wiring circuit board.

FIG. 10 is a cross-sectional view of a modified example (6) of the wiring circuit board.

FIG. 11 is a cross-sectional view of a modified example (7) of the wiring circuit board.

FIGS. 12A and 12B show a modified example (8) of the wired circuit board, FIG. 12A is a cross-sectional view corresponding to the A-A cross-sectional view of FIG. 2A, and FIG. 12B is a cross-sectional view corresponding to the B-B cross-sectional view of FIG. 2A.

FIG. 13 is a cross-sectional view of a modified example (9) of the wiring circuit board.

FIG. 14 is a cross-sectional view of a modified example (10) of the wiring circuit board.

FIG. 15 is a plan view of a modified example (11) of the wiring circuit board.

FIG. 16 is a plan view of a modified example (12) of the wiring circuit board.

FIG. 17 is a plan view of a modified example (13) of the wiring circuit board.

FIG. 18 is a plan view of a modified example (14) of the wiring circuit board.

### DESCRIPTION OF THE EMBODIMENT

### 1. Wiring Circuit Board

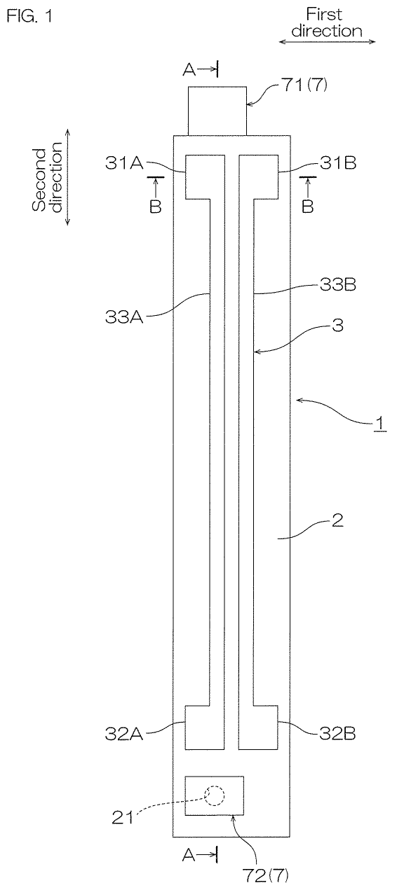

As shown in FIG. 1, in the present embodiment, a wiring circuit board 1 extends in a first direction and a second direction. The first direction is a direction in which a plurality of terminals 31A and 31B are arranged. The terminals 31A and 31B are described later. The second direction is perpendicular to the first direction. The shape of the wiring circuit board 1 is not limited to the present embodiment.

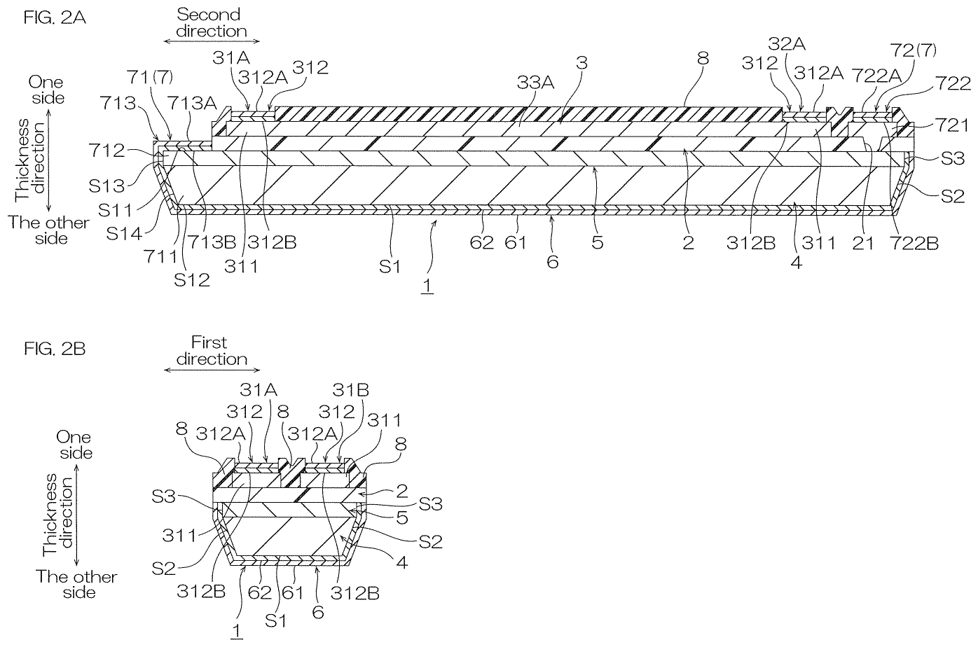

As shown in FIG. 2A, the wiring circuit board 1 includes a first insulating layer 2 as an example of an insulating layer, a first circuit pattern 3 (see FIG. 1), a metal support layer 4, a conductor layer 5, a covering layer 6, a second circuit pattern 7 (see FIG. 1), and a second insulating layer 8.

### (1) First Insulating Layer

The first insulating layer 2 insulates the metal support layer 4 and the conductor layer 5 from the first circuit pattern 3. The first insulating layer 2 is made of resin. Examples of the resin include polyimide, maleimide, epoxy resin, polybenzoxazole, and polyester. The first insulating layer 2 has a through hole 21.

### (2) First Circuit Pattern

The first circuit pattern 3 is disposed on one side of the first insulating layer 2 in the thickness direction of the first insulating layer 2. The thickness direction is orthogonal to the first direction and the second direction. The first circuit pattern 3 is disposed on a one-side surface of the first insulating layer 2 in the thickness direction.

As shown in FIG. 1, the first circuit pattern 3 includes a plurality of terminals 31A and 31B, a plurality of terminals 32A and 32B, and a plurality of wires 33A and 33B. The terminals 31A and 31B are arranged in the first direction. The terminal 31B is disposed away from the terminal 31A in the first direction. Each of the terminals 31A and 31B extends in the first direction and the second direction. Each of the terminals 31A and 31B has a substantially rectangular shape.

As shown in FIG. 2B, each of the terminals 31A and 31B has a conductor layer 311. Each of the terminals 31A and 31B may have a covering layer 312, if necessary.

The conductor layer 311 is disposed on the one-side surface of the first insulating layer 2 in the thickness direction. The conductor layer 311 is made of metal. Examples of the metal include copper, silver, gold, iron, aluminum, chromium, and the alloys thereof. From the viewpoint of obtaining good electrical properties, the conductor layer 311 is preferably made of copper.

The covering layer 312 covers a surface of the conductor layer 311. In the present embodiment, the covering layer 312 covers a central portion (a portion not covered with the second insulating layer 8) of a one-side surface of the conductor layer 311 in the thickness direction. The covering layer 312 has a surface layer 312A. The surface layer 312A is made of a metal different from the conductor layer 311. The surface layer 312A is made of, for example, gold. The covering layer 312 preferably has an intermediate layer 312B. The covering layer 312 may not have an intermediate layer 312B. The intermediate layer 312B is disposed between the conductor layer 311 and the surface layer 312A. The intermediate layer 312B is made of a metal different from the conductor layer 311 and the surface layer 312A. The intermediate layer 312B is made of, for example, nickel.

As shown in FIG. 1, the terminal 32A is disposed away from the terminal 31A in the second direction. The terminal 32B is disposed away from the terminal 31B in the second direction. The terminals 32A and 32B are arranged in the first direction. The terminal 32B is disposed away from the terminal 32A in the first direction. Each of the terminals 32A and 32B has, for example, a substantially rectangular shape. The descriptions of the terminals 32A and 32B are the same as the descriptions of the terminals 31A and 31B. Therefore, the descriptions of the terminals 32A and 32B are omitted.

The wire 33A electrically connects the terminal 31A and the terminal 32 A. The one end of the wire 33A is connected to the terminal 31A. Specifically, the one end of the wire 33A is connected to the conductor layer 311 (see FIGS. 1 and 2A) of the terminal 31A. The other end of the wire 33A is connected to the terminal 32A. Specifically, the other end of the wire 33A is connected to the conductor layer 311 (see FIG. 2A) of the terminal 32A.

The wire 33B electrically connects the terminal 31B and the terminal 32B. The one end of the wire 33B is connected to the terminal 31B. The other end of the wire 33B is connected to the terminal 32B.

The wires 33A and 33B are made of the same material as that of the conductor layer 311.

### (3) Metal Support Layer

As shown in FIGS. 2A and 2B, the metal support layer 4 is disposed on the other side of the first insulating layer 2 in the thickness direction. The metal support layer 4 is disposed on the opposite side to the first circuit pattern 3 with respect to the first insulating layer 2 in the thickness direction. The metal support layer 4 is insulated from the first circuit pattern 3 by the first insulating layer 2. The metal support layer 4 supports the first circuit pattern 3 and the first insulating layer 2. The entire metal support layer 4 overlaps the first insulating layer 2 in the thickness direction. Examples of the material of the metal support layer 4 include stainless steel and a copper alloy.

### (4) Conductor Layer

The conductor layer 5 is disposed on the other side of the first insulating layer 2 and on one side of the metal support layer 4 in the thickness direction. In other words, the conductor layer 5 is disposed between the first insulating layer 2 and the metal support layer 4 in the thickness direction. The conductor layer 5 is in contact with an other-side surface of the first insulating layer 2 and is in contact with a one-side surface of the metal support layer 4 in the thickness direction. The conductor layer 5 is disposed on the opposite side to the first circuit pattern 3 with respect to the first insulating layer 2 in the thickness direction. The conductor layer 5 is insulated from the first circuit pattern 3 by the first insulating layer 2. As shown in FIG. 2A, the conductor layer 5 extends from one end portion to the other end portion of the metal support layer 4 in the second direction, and as shown in FIG. 2B, extends from one end portion to the other end portion of the metal support layer 4 in the first direction. The conductor layer 5 does not have a wiring pattern. The entire conductor layer 5 overlaps the first insulating layer 2 in the thickness direction. The conductor layer 5 overlaps the entire first circuit pattern 3 in the thickness direction. The conductivity of the conductor layer 5 is higher than the conductivity of the metal support layer 4. The conductor layer 5 is, for example, made of copper.

A bonding layer that bonds the conductor layer 5 to the metal support layer 4 is preferably disposed between the metal support layer 4 and the conductor layer 5. The bonding layer is made of metal. Examples of the material of the bonding layer include chromium, nickel, titanium, and an alloy thereof.

A protective metal layer that protects the conductor layer 5 is preferably disposed between the conductor layer 5 and the first insulating layer 2. The protective metal layer is made of metal. Examples of the material of the protective metal layer include chromium, nickel, titanium, and an alloy thereof.

The bonding layer and the protective metal layer are not shown.

### (5) Covering Layer

The covering layer 6 covers the metal support layer 4. Specifically, the covering layer 6 covers an entire other-side surface S1 of the metal support layer 4 in the thickness direction. The covering layer 6 covers an entire end surface S2 of the metal support layer 4 and an entire end surface S3 of the conductor layer 5. In the present embodiment, the end surface S3 of the conductor layer 5 is continuous with the end surface S2 of the metal support layer 4 in the thickness direction. The end surface S3 of the conductor layer 5 is discontinuous with an end surface of the first insulating layer 2. The covering layer 6 has a surface layer 61. The covering layer 6 preferably includes an intermediate layer 62. The covering layer 6 may not have an intermediate layer 62. The intermediate layer 62 is disposed between the metal support layer 4 and the surface layer 61 and between the conductor layer 5 and the surface layer 61. The covering layer 6 is made of metal. Specifically, the surface layer 61 is made of a metal different from the metal support layer 4 and the conductor layer 5. The surface layer 61 is made of, for example, gold. The intermediate layer 62 is made of a metal different from the metal support layer 4, the conductor layer 5, and the surface layer 61. The intermediate layer 62 is, for example, made of nickel.

### (6) Second Circuit Pattern

As shown in FIG. 1, the second circuit pattern 7 is independent of the first circuit pattern 3. The second circuit pattern 7 includes a first terminal 71 and a second terminal 72. The first terminal 71 and the second terminal 72 are electrically connected through the conductor layer 5 (see FIG. 2A), and thus the second circuit pattern 7 functions as an electrical circuit independent of the first circuit pattern 3.

### (6-1) First Terminal

In the present embodiment, the first terminal 71 is disposed in one end portion of the wiring circuit board 1 in the second direction. The first terminal 71 has a prismatic shape extending in the second direction. The position and shape of the first terminal 71 are not limited to the present embodiment.

As shown in FIG. 2A, the first terminal 71 is continuous with the metal support layer 4. Therefore, the first terminal 71 is electrically connected to the metal support layer 4. The first terminal 71 does not overlap the first insulating layer 2 in the thickness direction. In the present embodiment, the first terminal 71 is disposed on one side in the second direction relative to the end surface of the first insulating layer 2. Therefore, a one-side surface of the first terminal 71 in the thickness direction is exposed from the first insulating layer 2. The first terminal 71 does not overlap the second insulating layer 8 in the thickness direction.

The first terminal 71 includes a metal layer 711, a terminal conductor layer 712, and a terminal covering layer 713.

The metal layer 711 is continuous with the metal support layer 4. The metal layer 711 is a single layer unified with the metal support layer 4. The metal layer 711 is made of the same material as that of the metal support layer 4. In the present embodiment, the metal layer 711 extends from one end portion on one side of the metal support layer 4 to one side (outside) in the second direction.

The terminal conductor layer 712 is disposed on one side of the metal layer 711 in the thickness direction. The terminal conductor layer 712 is disposed on a one-side surface of the metal layer 711 in the thickness direction. The terminal conductor layer 712 is continuous with the conductor layer 5. The terminal conductor layer 712 is a single layer unified with the conductor layer 5. The terminal conductor layer 712 is made of the same material as that of the conductor layer 5. In the present embodiment, the terminal conductor layer 712 extends from one end portion on one side of the conductor layer 5 to one side (outside) in the second direction.

The terminal covering layer 713 covers the terminal conductor layer 712. Specifically, the terminal covering layer 713 covers the entire one-side surface S11 of the terminal conductor layer 712 in the thickness direction. Further, the terminal covering layer 713 covers the entire other-side surface S12 of the metal layer 711 in the thickness direction, the entire end surface S13 of the terminal conductor layer 712, and the entire end surface S14 of the metal layer 711. In the present embodiment, the end surface S13 of the terminal conductor layer 712 is continuous with the end surface S14 of the metal layer 711 in the thickness direction. The terminal covering layer 713 has a surface layer 713A. The terminal covering layer 713 preferably has an intermediate layer 713B. The terminal covering layer 713 may not have an intermediate layer 713B. The intermediate layer 713B is disposed between the metal layer 711 and the surface layer 713A and between the terminal conductor layer 712 and the surface layer 713A. The terminal covering layer 713 is continuous with the covering layer 6. Specifically, the surface layer 713A is continuous with the surface layer 61 of the covering layer 6. The intermediate layer 713B is continuous with the intermediate layer 62 of the covering layer 6. The surface layer 713A is made of a metal different from the metal layer 711 and the terminal conductor layer 712. The surface layer 713A is made of the same material as that of the surface layer 61 of the covering layer 6. The surface layer 713A is made of, for example, gold. The intermediate layer 713B is made of a metal different from those of the metal layer 711, the terminal conductor layer 712, and the surface layer 713A. The intermediate layer 713B is made of the same material as that of the intermediate layer 62 of the covering layer 6. The intermediate layer 713B is made of, for example, nickel. That is, the terminal covering layer 713 is made of metal.

### (6-2) Second Terminal

As shown in FIG. 1, in the present embodiment, the second terminal 72 is disposed in the other end portion of the wiring circuit board 1 in the second direction. The second terminal 72 has a substantially rectangular shape. The position and shape of the second terminal 72 are not limited to the present embodiment.

As shown in FIG. 2A, the second terminal 72 is disposed on one side of the first insulating layer 2 in the thickness direction. The second terminal 72 is electrically connected to the conductor layer 5 through a through hole 21 of the first insulating layer 2. The second terminal 72 includes a conductor layer 721 in the same manner as the terminal 31A of the first circuit pattern 3. The second terminal 72 may have a covering layer 722 if necessary.

The conductor layer 721 is disposed on the one-side surface of the first insulating layer 2 in the thickness direction. The conductor layer 721 is made of the same material as the terminal 31A of the first circuit pattern 3.

The covering layer 722 covers a surface of the conductor layer 721. In the present embodiment, the covering layer 722 covers a central portion (a portion not covered with the second insulating layer 8) of a one-side surface of the conductor layer 721 in the thickness direction. The covering layer 722 has a surface layer 722A. The surface layer 722A is made of, for example, gold. The covering layer 722 preferably has an intermediate layer 722B. The covering layer 722 may not have an intermediate layer 722B. The intermediate layer 722B is disposed between the conductor layer 721 and the surface layer 722A. The intermediate layer 722B is made of, for example, nickel.

### (7) Second Insulating Layer

The second insulating layer 8 is disposed on one side of the first insulating layer 2 in the thickness direction. The second insulating layer 8 is disposed on the one-side surface of the first insulating layer 2 in the thickness direction. The second insulating layer 8 is made of resin. Examples of the resin include polyimide, maleimide, epoxy resin, polybenzoxazole, and polyester. The second insulating layer 8 covers the wires 33A and 33B (see FIG. 1). The second insulating layer 8 may cover a peripheral edge portion of each of the terminals 31A, 31B, 32A, and 32B and the second terminal 72. The second insulating layer 8 does not cover a central portion of each of the terminals 31A, 31B, 32A, and 32B and the second terminal 72.

### 2. Method of Producing Wiring Circuit Board

Next, a method of producing the wiring circuit board 1 is described.

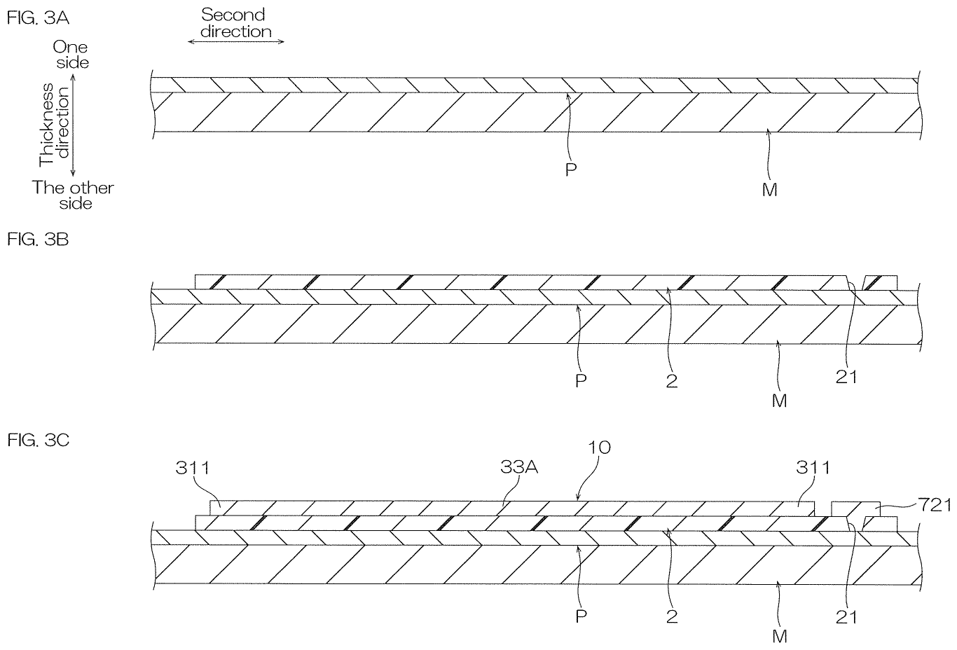

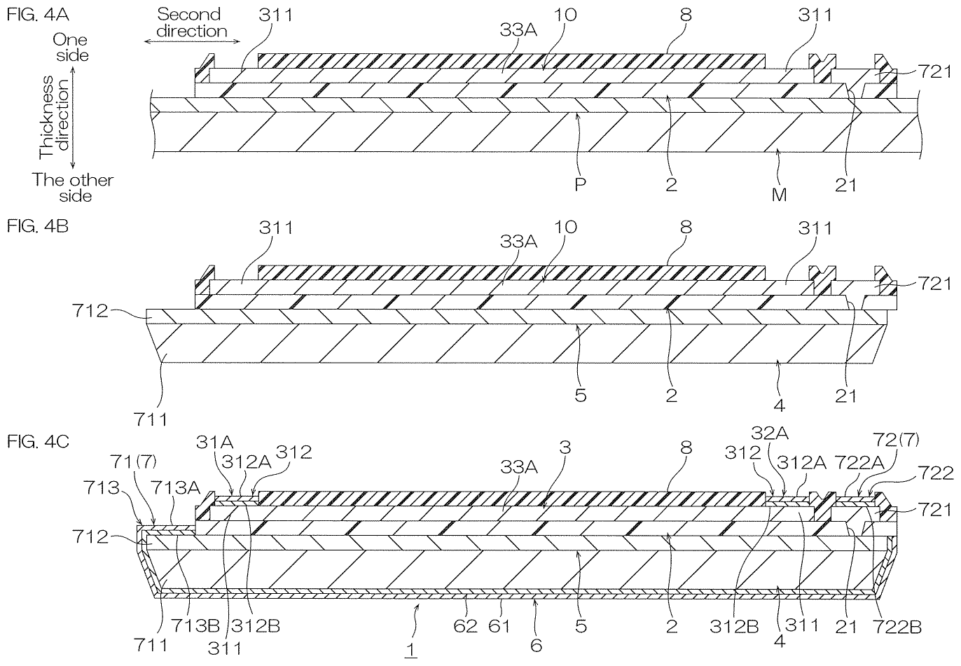

The method of producing the circuit board 1 includes a conductor layer forming step (see FIG. 3A), a first insulating layer forming step (see FIG. 3B), a conductive pattern forming step (see FIG. 3C), a second insulating layer forming step (see FIG. 4A), an outer shape trimming step (see FIG. 4B), and a covering layer forming step (see FIG. 4C).

### (1) Conductor Layer Forming Step

As shown in FIG. 3A, in the conductor layer forming step, a conductor layer P is formed on the entire surface of a substrate M made of metal, for example, by electrolytic plating.

Specifically, first, the above-described bonding layer is formed on a one-side surface of the substrate M in the thickness direction. The bonding layer is formed, for example, by sputtering.

Next, the conductor layer P is formed on the bonding layer, for example, by electrolytic plating.

### (2) First Insulating Layer Forming Step

Next, as shown in FIG. 3B, in the first insulating layer forming step, a first insulating layer 2 is formed on a one-side surface of the conductor layer P.

Specifically, in the first insulating layer forming step, first, the above-described protective metal layer is formed on the one-side surface of the conductor layer P in the thickness direction. The protective metal layer is formed, for example, by sputtering.

Next, a solution (varnish) of a photosensitive resin is applied on the conductor layer P and dried to form a coating film of the photosensitive resin. Next, the coating film of the photosensitive resin is exposed to light and developed. In this manner, a first insulating layer 2 is obtained.

### (3) Conductive Pattern Forming Step

Next, as shown in FIG. 3C, in the conductive pattern forming step, a conductive pattern 10 is formed on the first insulating layer 2. The conductive pattern 10 includes a conductor layer 311 of each of terminals 31A, 31B, 32A, and 32B, a wires 33A and 33B, and a conductor layer 721 of the second terminal 72.

Specifically, first, in the thickness direction, a seed layer is formed on a one-side surface of the first insulating layer 2 and the one-side surface of the conductor layer P. The seed layer is formed, for example, by sputtering. Examples of the material of the seed layer include, for example, chromium, copper, nickel, titanium, and an alloy thereof.

Next, the seed layer is covered with a plating resist.

Next, the plating resist is exposed to light and developed. Then, the plating resist in the portion where the conductive pattern 10 is to be formed is removed, and the seed layer is exposed in the portion where the conductive pattern 10 is to be formed. On the other hand, the plating resist in the portion where the conductive pattern 10 is not formed remains.

Next, the conductive pattern 10 is formed on the exposed seed layer by electrolytic plating. After the electrolytic plating is completed, the plating resist is released, and the seed layer exposed due to the release of the plating resist is removed by etching.

In this manner, a conductive pattern 10 is formed on the first insulating layer 2.

### (4) Second Insulating Layer Forming Step

Next, as shown in FIG. 4A, in the second insulating layer forming step, a second insulating layer 8 is formed on the first insulating layer 2.

Specifically, in the second insulating layer forming step, first, a solution (varnish) of a photosensitive resin is applied onto the conductive pattern 10, the first insulating layer 2, and the conductor layer P and dried to form a coating film of the photosensitive resin.

Next, the coating film of the photosensitive resin is exposed to light and developed. In this manner, a second insulating layer 8 is formed on the first insulating layer 2.

### (5) Outer Shape Trimming Step

Next, as shown in FIG. 4B, in the outer shape trimming step, the substrate M and the conductor layer P are etched to form a metal support layer 4, a conductor layer 5, a metal layer 711, and a terminal conductor layer 712.

### (6) Covering Layer Forming Step

Next, as shown in FIG. 4C, in the covering layer forming step, for example, electroless nickel plating and electroless gold plating are sequentially carried out to simultaneously form a covering layer 312, a covering layer 722, a covering layer 6, and a terminal covering layer 713.

As described above, the above-described wiring circuit board 1 is obtained.

### 3. Operations and Effects

(1) According to the wiring circuit board 1, as shown in FIGS. 1 and 2A, the first terminal 71 of the second circuit pattern 7 has a metal layer 711 that is continuous with the metal support layer 4.

Therefore, the second circuit pattern 7 independent of the first circuit pattern 3 can be designed by using the metal support layer 4 that supports the first circuit pattern 3.

As a result, the degree of freedom in circuit design can be improved.

In addition, the metal layer 711 of the first terminal 71 is continuous with the metal support layer 4, and thus a decrease in the stiffness of the metal support layer 4 caused by forming the second circuit pattern 7 can be suppressed as compared with a case where the second circuit pattern 7 is formed by separating a part of the metal support layer 4 from the metal support layer 4.

(2) According to the circuit board 1, as shown in FIG. 2A, the first terminal 71 includes a terminal covering layer 713 that is made of metal and covers the metal layer 711.

Therefore, the metal layer 711 can be protected by the terminal covering layer 713.

(3) According to the circuit board 1, as shown in FIG. 2A, the terminal covering layer 713 is continuous with the covering layer 6 covering the metal support layer 4.

Therefore, the metal support layer 4 can be protected by the covering layer 6.

Furthermore, the terminal covering layer 713 can be formed at the same time as the formation of the covering layer 6, and thus an increase in the number of steps can be suppressed.

(4) As shown in FIGS. 2A and 2B, the wiring circuit board 1 includes a conductor layer 5. The conductor layer 5 is disposed between the first insulating layer 2 and the metal support layer 4 in the thickness direction. The first terminal 71 further includes a terminal conductor layer 712 continuous with the conductor layer 5.

Therefore, a conductor layer 5 having high conductivity is provided between the first insulating layer 2 and the metal support layer 4, and the second circuit pattern 7 independent of the first circuit pattern 3 can be designed by using the conductor layer 5.

As a result, it is possible to improve the conductivity performance of the second circuit pattern 7 while improving the degree of freedom in circuit design.

(5) According to the wiring circuit board 1, as shown in FIG. 2A, the terminal covering layer 713 covers not only the metal layer 711 but also the terminal conductor layer 712.

Therefore, the terminal conductor layer 712 can also be protected by the terminal covering layer 713.

(6) According to the circuit board 1, as shown in FIGS. 1 and 2A, the second circuit pattern 7 includes a second terminal 72. The second terminal 72 is disposed on one side of the first insulating layer 2 in the thickness direction, and is electrically connected to the conductor layer 5 through the through hole 21.

Therefore, the first terminal 71 and the second terminal 72 can be electrically connected through the conductor layer 5.

This enables the transmission of an electric signal or supply of electric power between the first terminal 71 and the second terminal 72 through the conductor layer 5.

(7) According to the wiring circuit board 1, as shown in FIGS. 1 and 2A, the one-side surface of the first terminal 71 in the thickness direction is exposed from the first insulating layer 2.

Therefore, the one-side surface of the first terminal 71 in the thickness direction can be used as a bonding surface with an electronic component.

### 4. Modified Examples

Modified examples are described. In the modified examples, the same members as in the above-described embodiment are given the same numerical references and the descriptions thereof are omitted.

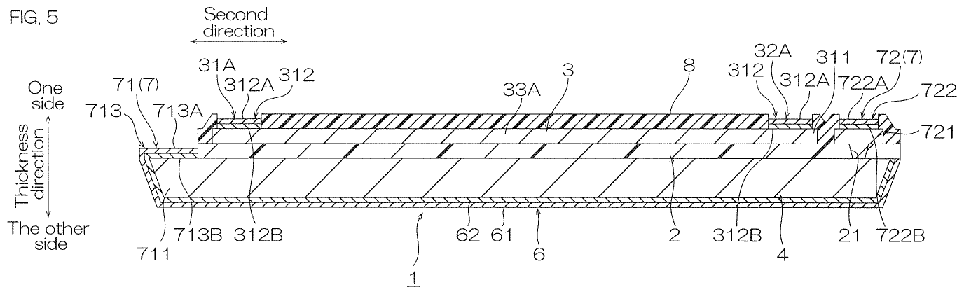

(1) As shown in FIG. 5, the wiring circuit board 1 may not include a conductor layer 5 and a terminal conductor layer 712. In this case, the metal support layer 4 is in contact with an other-side surface of the first insulating layer 2 in the thickness direction. The second terminal 72 is electrically connected to the metal support layer 4 through the through hole 21 of the first insulating layer 2.

In this manner, the first terminal 71 and the second terminal 72 can be electrically connected through the metal support layer 4.

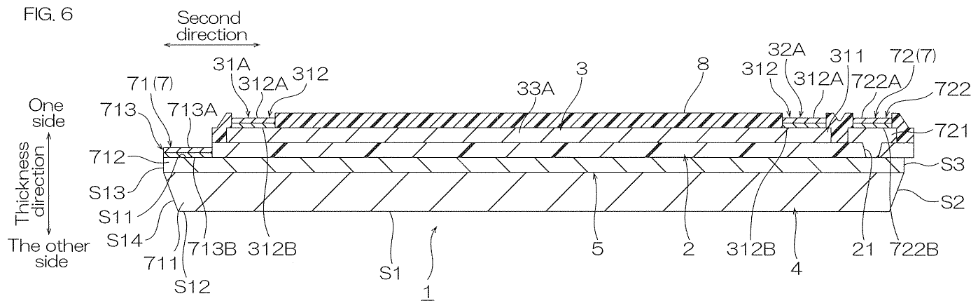

(2) As shown in FIG. 6, the wiring circuit board 1 may not have a covering layer 6. The terminal covering layer 713 may cover the one-side surface S11 of the terminal conductor layer 712 in the thickness direction, and may not cover the other-side surface S12 of the metal layer 711 in the thickness direction, the end surface S13 of the terminal conductor layer 712, and the end surface S14 of the metal layer 711.

When the wiring circuit board 1 does not have a covering layer 6, the covering layer forming step may be carried out after the second insulating layer forming step and before the outer shape trimming step.

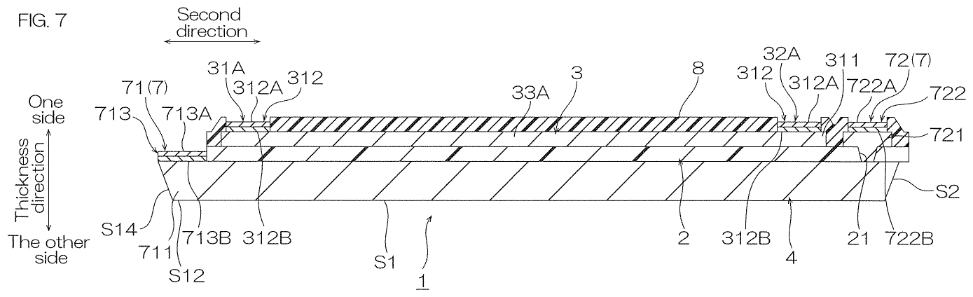

(3) As shown in FIG. 7, the wiring circuit board 1 may not include a conductor layer 5, a terminal conductor layer 712, and a covering layer 6. The terminal covering layer 713 may cover the one-side surface of the metal layer 711 in the thickness direction and may not cover the other-side surface S12 of the metal layer 711 in the thickness direction and the end surface S14 of the metal layer 711.

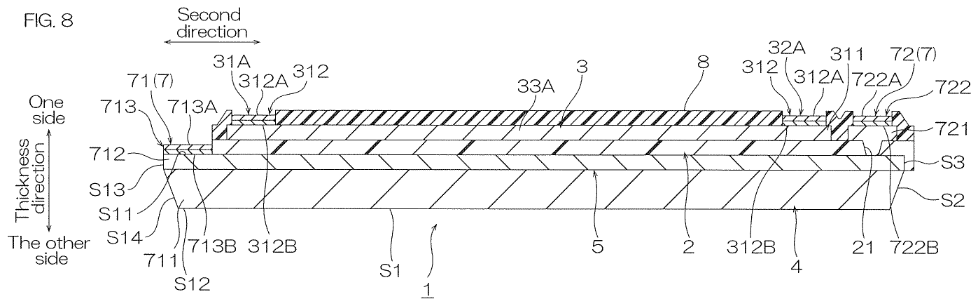

(4) As shown in FIG. 8, when the wiring circuit board 1 does not have a covering layer 6, the end surface S3 of the conductor layer 5 may be covered with the first insulating layer 2.

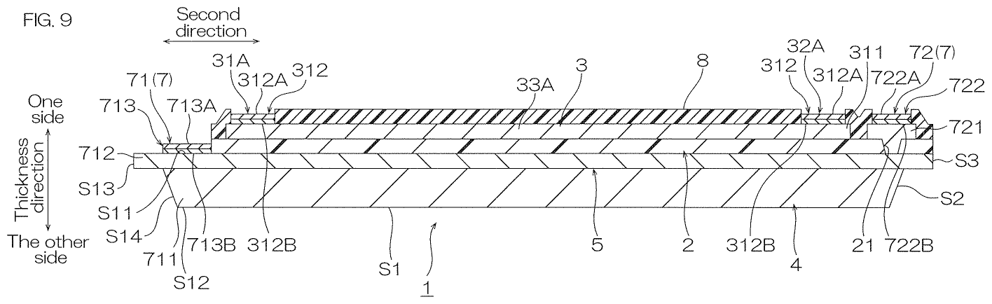

(5) The end surface S2 of the metal support layer 4 may be discontinuous with the end surface S3 of the conductor layer 5. Specifically, as shown in FIG. 9, the end surface S2 of the metal support layer 4 may be disposed inward away from the end surface S3 of the conductor layer 5. The end surface S3 of the conductor layer 5 may be continuous with the end surface of the first insulating layer 2. The end surface S14 of the metal layer 711 may be discontinuous with the end surface S13 of the terminal conductor layer 712. The end surface S14 of the metal layer 711 may be disposed inward away from the end surface S13 of the terminal conductor layer 712.

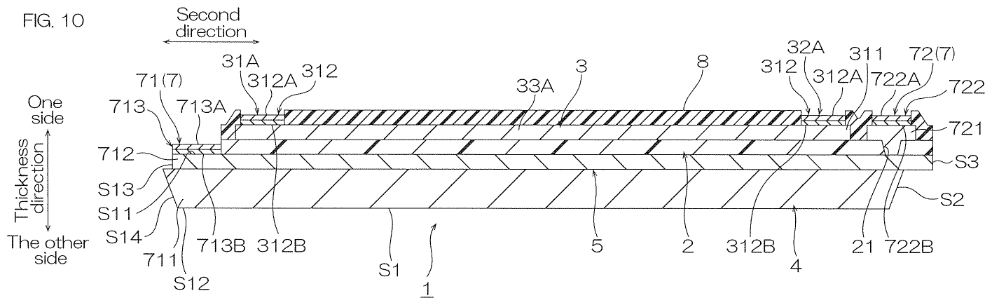

(6) As shown in FIG. 10, the end surface S13 of the terminal conductor layer 712 may be disposed inward away from the end surface S14 of the metal layer 711.

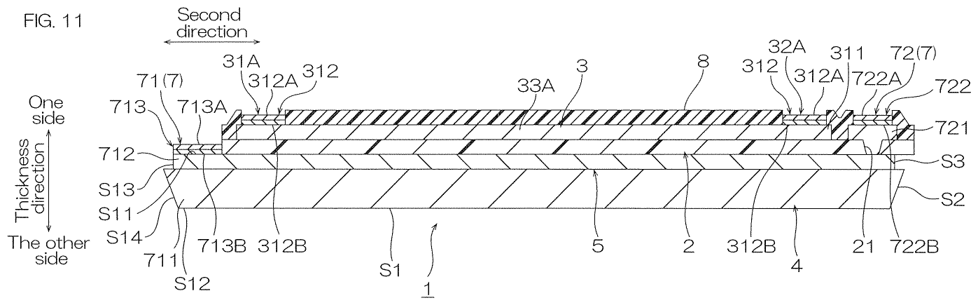

(7) As shown in FIG. 11, the end surface S3 of the conductor layer 5 may be disposed inward away from the end surface S2 of the metal support layer 4.

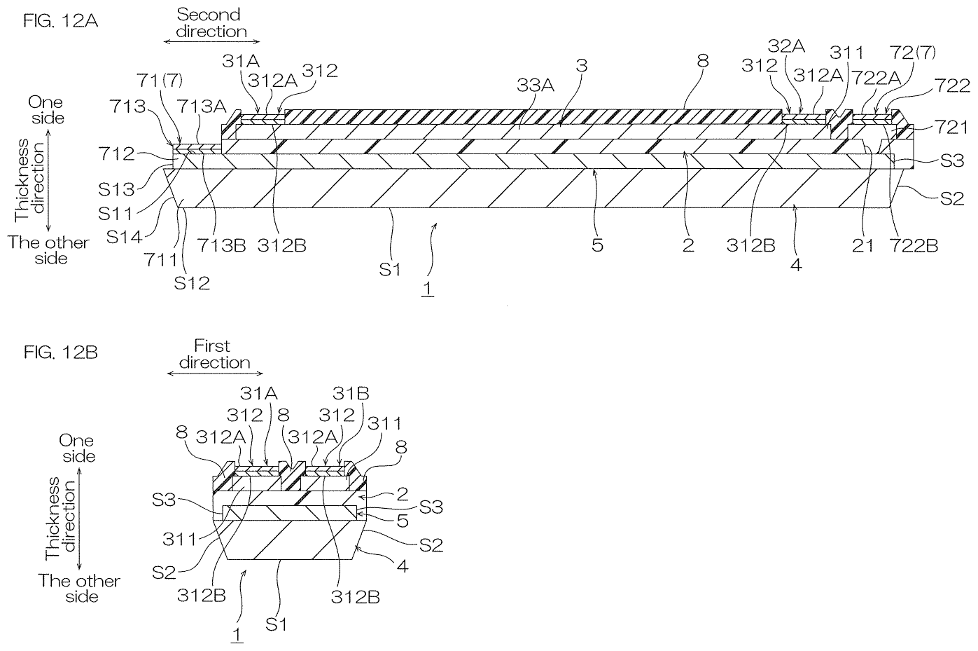

(8) As shown in FIG. 12A, in the second direction, the end surface S3 of the conductor layer 5 may be disposed inward away from the end surface S2 of the metal support layer 4, and may be covered with the first insulating layer 2. In this case, as shown in FIG. 12B, also in the first direction, the end surface S3 of the conductor layer 5 may be disposed inward away from the end surface S2 of the metal support layer 4, and may be covered with the first insulating layer 2.

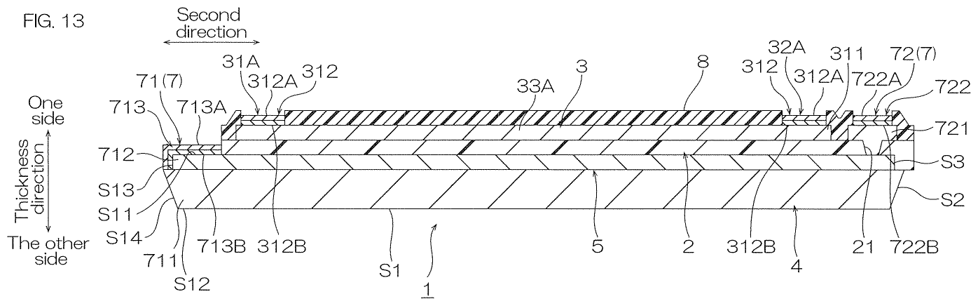

(9) As shown in FIG. 13, in the modified example (8) (see FIG. 12A), the terminal covering layer 713 may cover the one-side surface S11 of the terminal conductor layer 712 in the thickness direction and the end surface S13 of the terminal conductor layer 712, and may not cover the other-side surface S12 of the metal layer 711 in the thickness direction and the end surface S14 of the metal layer 711.

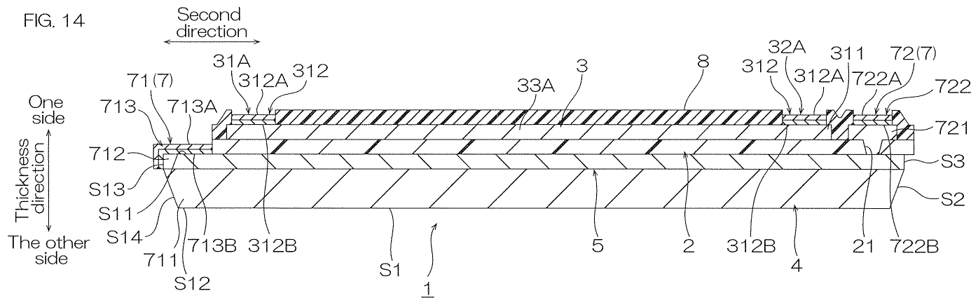

(10) As shown in FIG. 14, in the above-described embodiment (see FIG. 2A), the terminal covering layer 713 may cover the one-side surface S11 of the terminal conductor layer 712 in the thickness direction and the end surface S13 of the terminal conductor layer 712, and may not cover the other-side surface S12 of the metal layer 711 in the thickness direction and the end surface S14 of the metal layer 711.

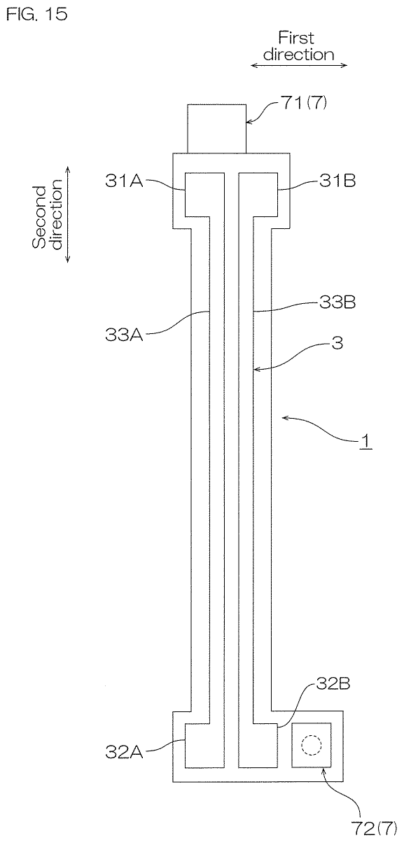

(11) The position of the first terminal 71 and the position of the second terminal 72 are not limited to the above-described embodiment. As shown in FIG. 15, the second terminal 72 may be arranged with the terminals 32A and 32B in the first direction.

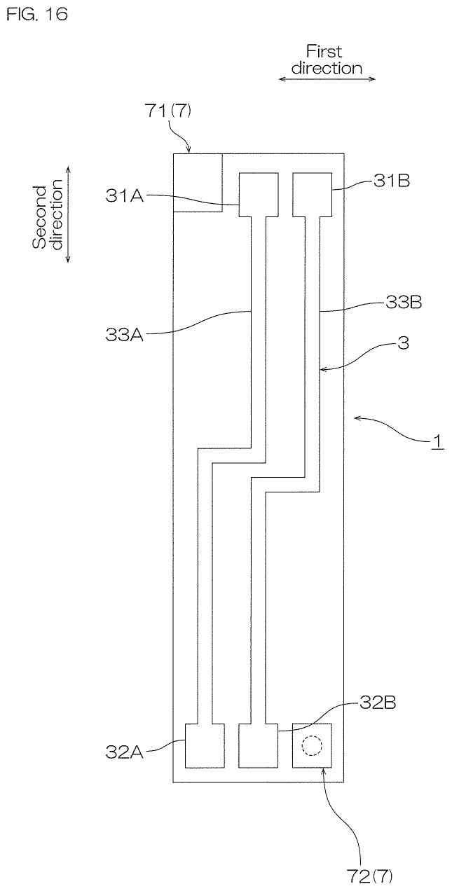

(12) As shown in FIG. 16, the first terminal 71 may be arranged with the terminals 31A and 31B in the first direction, and the second terminal 72 may be arranged with the terminals 32A and 32B in the first direction.

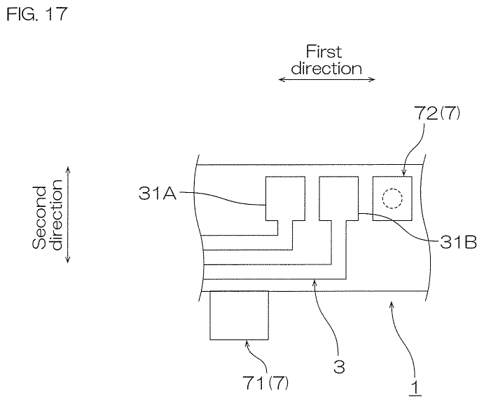

(13) As shown in FIG. 17, the wiring circuit board 1 may have a predetermined width in the second direction and extend in the first direction. The second terminal 72 may be arranged with the terminals 31A and 31B in the first direction. The first terminal 71 may be disposed away from the second terminal 72 in the first direction. The first terminal 71 may be disposed in the other end portion of the wiring circuit board 1 in the second direction.

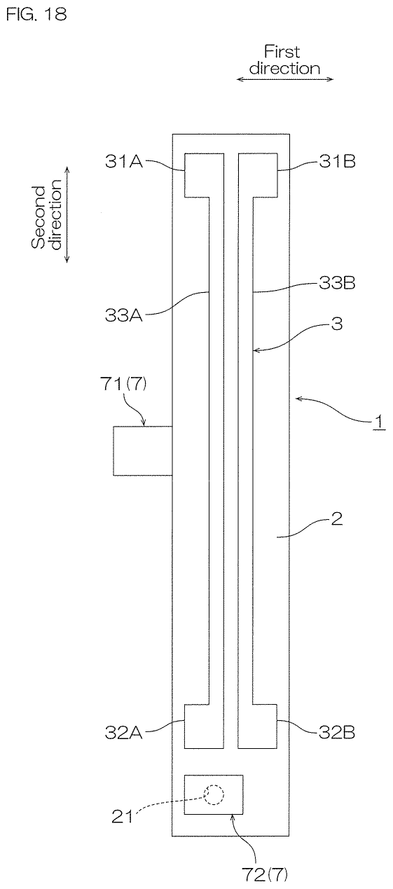

(14) As shown in FIG. 18, the first terminal 71 may be disposed between the terminal 31A and the terminal 32A in the second direction. In other words, the first terminal 71 is arranged with the wires 33A and 33B in the first direction. The first terminal 71 is disposed at the opposite side to the wire 33B with respect to the wire 33A in the first direction.

(15) Also in the above-described modified examples (1) to (14), it is possible to improve the degree of freedom in circuit design as in the above-described embodiment.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The wiring circuit board of the present invention can be used for connecting electronic components.

### DESCRIPTION OF REFERENCE NUMERALS

1 Wiring circuit board
3 First circuit pattern
4 Metal support layer
5 Conductor layer
6 Covering layer
7 Second circuit pattern
71 First terminal
72 Second terminal
711 Metal layer
712 Terminal conductor layer
713 Terminal covering layer

1. A wiring circuit board comprising:
an insulating layer;
a first circuit pattern disposed on one side of the insulating layer in a thickness direction of the insulating layer;
a metal support layer disposed on an opposite side to the first circuit pattern with respect to the insulating layer in the thickness direction, insulated from the first circuit pattern by the insulating layer, and supporting the first circuit pattern and the insulating layer; and
a second circuit pattern independent of the first circuit pattern,
wherein the second circuit pattern includes a first terminal having a metal layer continuous with the metal support layer.

2. The wiring circuit board according to claim 1,
wherein the first terminal further includes a terminal covering layer made of metal and covering the metal layer.

3. The wiring circuit board according to claim 2, further comprising:
a covering layer made of metal and covering the metal support layer,
wherein the terminal covering layer is continuous with the covering layer.

4. The wiring circuit board according to claim 1, further comprising:
a conductor layer disposed between the insulating layer and the metal support layer in the thickness direction and having a conductivity higher than a conductivity of the metal support layer.

5. The wiring circuit board according to claim 4,
wherein the first terminal further includes a terminal conductor layer continuous with the conductor layer.

6. The wiring circuit board according to claim 5,
wherein the first terminal further includes a terminal covering layer made of metal and covering the terminal conductor layer.

7. The wiring circuit board according to claim 6, further comprising:
a covering layer made of metal and covering the metal support layer,
wherein the terminal covering layer is continuous with the covering layer.

8. The wiring circuit board according to claim 5,
wherein the second circuit pattern further includes a second terminal disposed on one side of the insulating layer in the thickness direction and electrically connected to the conductor layer.

9. The wiring circuit board according to claim 1,
wherein the second circuit pattern further includes a second terminal disposed on one side of the insulating layer in the thickness direction and electrically connected to the metal support layer.

10. The wiring circuit board according to claim 1,
wherein a one-side surface of the first terminal in the thickness direction is exposed from the insulating layer.
